(19) United States
(12) Patent Application Publication
(10) Pub. No.: US 2025/0106999 A1
(43) Pub. Date: Mar. 27, 2025

(54) ANTENNA-INTEGRATED RADIO PRODUCT AND METHOD FOR PRODUCING THE SAME

(71) Applicant: Telefonaktiebolaget LM Ericsson (publ), Stockholm (SE)

(72) Inventors: Xuejun Sun, Beijing (CN); Junming Li, Beijing (CN); Peng Liu, Beijing (CN); Donghai Yu, Beijing (CN)

(21) Appl. No.: 18/728,619

(22) PCT Filed: Oct. 25, 2022
(86) PCT No.: PCT/CN2022/127335

§ 371 Date: Jul. 12, 2024

(30) Foreign Application Priority Data
Jan. 12, 2022 (WO) PCT/CN2022/071608

(51) Int. Cl. H05K 1/14; H01Q 21/06; H05K 1/18; H05K 3/34; H05K 3/36

(52) U.S. Cl. CPC H05K 1/144; H01Q 21/06; H05K 1/181; H05K 3/341; H05K 3/36; H05K 2201/0776; H05K 2201/1006; H05K 2201/10098

(57) ABSTRACT

An antenna-integrated radio product and a method for producing the same is provided. According to an embodiment, the antenna-integrated radio product comprises an antenna module and a radio module. The antenna module comprises a plurality of antenna elements and a power divider. The radio module comprises a radio board and a plurality of radio components. The antenna module and the radio components are soldered to opposite sides of the radio board.

### TECHNICAL FIELD

The present disclosure generally relates to the technical field of communication device, and more particularly, to an antenna-integrated radio (AIR) product and a method for producing the same.

### BACKGROUND

This section introduces aspects that may facilitate better understanding of the present disclosure. Accordingly, the statements of this section are to be read in this light and are not to be understood as admissions about what is in the prior art or what is not in the prior art.

Base station (BS) is an important part of a mobile communication system, and may include a radio unit (RU) and an antenna unit (AU). In traditional BS solution, remote radio unit (RRU) and AU are separated as two independent units and hung on high constructions, like tall buildings, high walls, towers and lamp stands. Considering the installation/fixation/occupation, smaller volume and lighter weight is always an important evolution direction in BS design, including Legacy BS, Street Macro, Micro, Small Cell, and Advanced Antenna System (AAS).

Recent years, with the development of the 5th Generation (5G) communication, Multiple-Input and Multiple-Output (MIMO) technology is widely used, in which the demands for small size high performance radio are growing rapidly. Moreover, volume/size is always related to power and Passive Inter-Modulation (PIM) performance. The study of how to get better performance in limited size or how to get enough performance in minimum size becomes more and more important.

Methods for reducing the size of products such as BS may include: 1) reducing the size of each component to its minimum; and 2) designing a high-integrated module in which multiple components are integrated into a single module. For example, 5G radio and multi-band antennas may be integrated into a single enclosure to form an AIR product.

FIG. 1 shows a first existing AIR product, in which an FU 3 comprising metal cavity filters is arranged between an AU and an RU. The AU includes an antenna board 10, antenna elements 11, and an antenna radome 12. The RU includes a radio board 20, a radio cover 22, a radio heatsink 23, and radio components (not shown) disposed on one or both sides of the radio board 20. The FU 3 is connected to the antenna board 10 of the AU and the radio board 20 of the RU through RF connectors 4.

FIG. 2 shows a second existing AIR product, in which ceramic waveguide (CWG) filters 3′ are used instead of metal cavity filters. As shown in FIG. 2, the CWG filters 3′ are soldered on the radio board 20 of the RU, and the antenna board 10 of the AU is connected to the radio board 20 of the RU through RF connectors 4. The antenna board 10 may be integrated with the radio cover 22.

FIG. 3 shows a third existing AIR product, in which CWG filters 3′ are soldered on the back side of the antenna board 10 of the AU to form an antenna filter unit (AFU). The AFU is connected to the radio board 20 of the RU through RF connectors 4.

FIG. 4 shows a fourth existing AIR product, in which the antenna elements 11 and the radio components 21 are disposed on opposite sides of a single board 5 that has at least one radio layer and at least one antenna layer. In such a one board solution, FUs 3″ are arranged between the board 5 and the radio heatsink 23, and RF connectors can be dispensed with.

The one board solution shown in FIG. 4 achieves a high integration level to reduce size/weight of the product. However, the AU and the RU have different requirements on the Printed Circuit Board (PCB), and it is difficult to manufacture the board 5 which satisfies the requirements for both the AU and the RU. Thus, the current one board solution is much more expensive than separately producing an antenna board and a radio board.

### SUMMARY

This summary is provided to introduce a selection of concepts in a simplified form that are further described below in the detailed description. This summary is not intended to identify key features or essential features of the claimed subject matter, nor is it intended to be used to limit the scope of the claimed subject matter.

One of the objects of the disclosure is to provide an AIR product, which can achieve a high integration level while reducing costs.

According to a first aspect of the disclosure, there is provided an AIR product which comprises an antenna module and a radio module. The antenna module comprises a plurality of antenna elements and a power divider. The radio module comprises a radio board and a plurality of radio components. The antenna module and the radio components are soldered to opposite sides of the radio board.

In an embodiment of the disclosure, the antenna module comprises an antenna board, the antenna elements and the power divider are soldered to a first side of the antenna board, and a second side of the antenna board is soldered to the radio board.

In an embodiment of the disclosure, the size of the antenna board is different from the size of the radio board.

In an embodiment of the disclosure, the antenna elements soldered to the antenna board are grouped in multiple bands.

In an embodiment of the disclosure, the antenna module further comprises an impedance transformer and a calibration network soldered to the first side of the antenna board.

In an embodiment of the disclosure, the antenna module is directly soldered to the radio board. The term “directly soldered” herein means that no antenna board is provided.

In an embodiment of the disclosure, the antenna module further comprises an impedance transformer and a calibration network.

In an embodiment of the disclosure, the radio components comprises a surface mounted filter and/or one or more baseband components selected from a group consisted of a field-programmable gate array (FPGA), a digital signal processor (DSP), a central processing unit (CPU), and a random-access memory (RAM).

In an embodiment of the disclosure, wherein further radio components are provided on a side of the radio board to which the antenna module is soldered.

According to a second aspect of the disclosure, there is provided a method for producing an AIR product, the AIR product comprising an antenna module and a radio module, the antenna module comprising an antenna board and a plurality of antenna elements, the radio module comprising a radio board and a plurality of radio components. The method comprises steps of: a) soldering the antenna elements to a first side of the antenna board; b) soldering the radio components to a first side of the radio board; c) putting the antenna board together with the radio board, such that a second side of the antenna board that is opposite to the first side thereof faces a second side of the radio board that is opposite to the first side thereof; and d) soldering the second side of the antenna board to the second side of the radio board.

In an embodiment of the disclosure, the step a) or the step b) is carried out simultaneously with, before or after the step d).

In an embodiment of the disclosure, the steps a), b) and d) are carried out in the same reflow oven.

According to a third aspect of the disclosure, there is provided a method for producing an AIR product, the AIR product comprising an antenna module and a radio module, the antenna module comprising a plurality of antenna elements, a power divider, an impedance transformer, and a calibration network, the radio module comprising a radio board and a plurality of radio components. The method comprises steps of: a) soldering the radio components to a first side of the radio board; b) putting the antenna elements, the power divider, the impedance transformer, and the calibration network on a second side of the radio board that is opposite to the first side thereof; c) soldering the antenna elements and the power divider to the second side of the radio board; and d) soldering the impedance transformer and the calibration network to the second side of the radio board.

In an embodiment of the disclosure, the step c) or the step d) is carried out simultaneously with, before or after the step a).

In an embodiment of the disclosure, the steps a), c) and d) are carried out in the same reflow oven.

### BRIEF DESCRIPTION OF THE DRAWINGS

These and other objects, features and advantages of the disclosure will become apparent from the following detailed description of illustrative embodiments thereof, which are to be read in connection with the accompanying drawings.

FIG. 1 is a diagram showing a first existing AIR product;

FIG. 2 is a diagram showing a second existing AIR product;

FIG. 3 is a diagram showing a third existing AIR product;

FIG. 4 is a diagram showing a fourth existing AIR product;

FIG. 5 is a diagram showing a portion of a board of the AIR product shown in FIG. 4;

FIG. 6 is a diagram showing a portion of an AIR product according to an embodiment of the disclosure;

FIG. 7 is a diagram showing a process for producing the AIR product shown in FIG. 6;

FIG. 8 is a diagram showing another process for producing the AIR product shown in FIG. 6;

FIGS. 9 to 11 show examples of different dimension for a radio PCB and an antenna PCB.

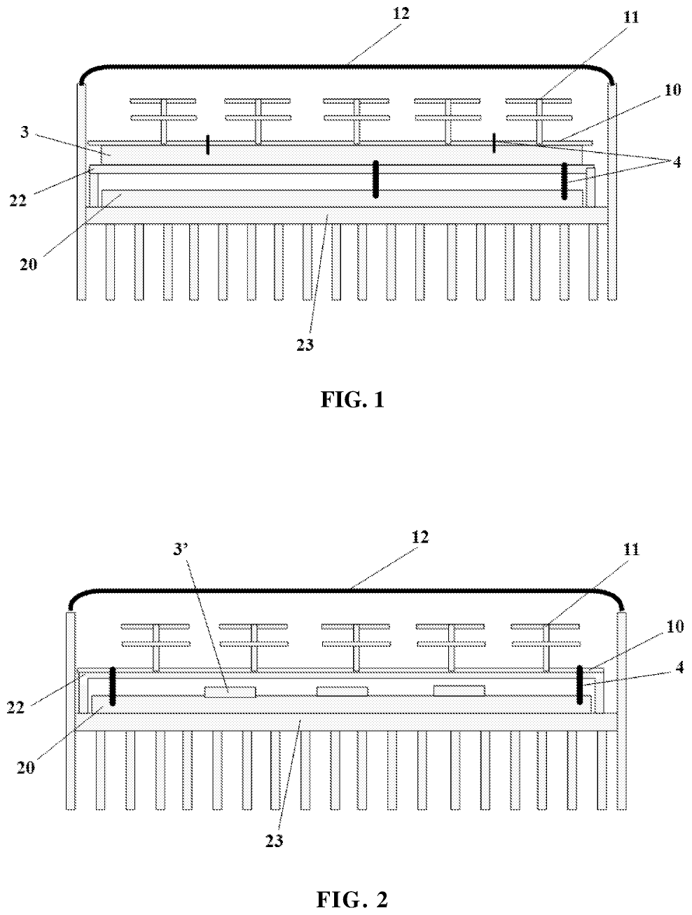

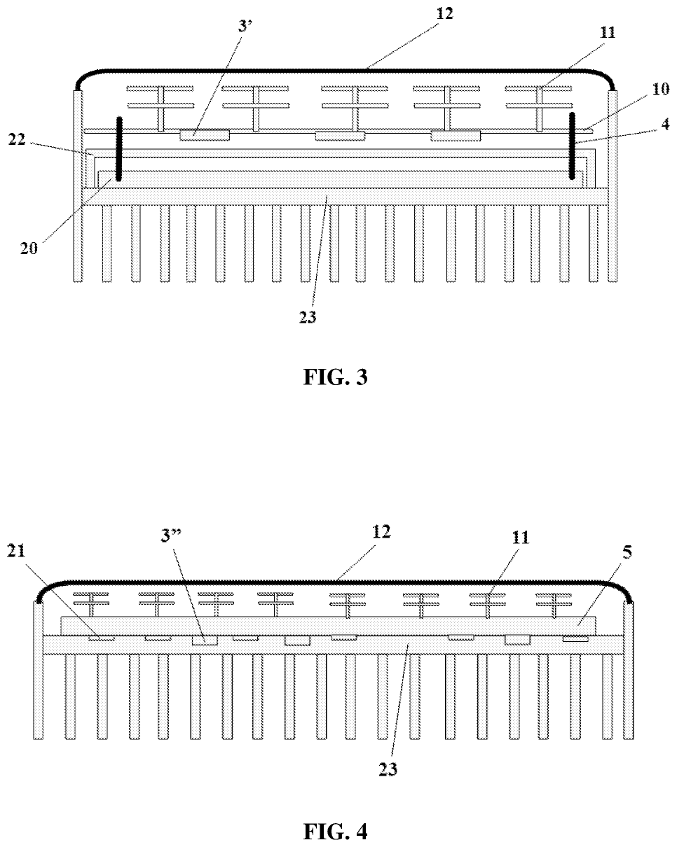

### DETAILED DESCRIPTION

The embodiments of the present disclosure are described in detail with reference to the accompanying drawings. It should be understood that these embodiments are discussed only for the purpose of enabling those skilled in the art to better understand and thus implement the present disclosure, rather than suggesting any limitations on the scope of the present disclosure. Reference throughout this specification to features, advantages, or similar language does not imply that all of the features and advantages that may be realized with the present disclosure should be or are in any single embodiment of the disclosure. Rather, language referring to the features and advantages is understood to mean that a specific feature, advantage, or characteristic described in connection with an embodiment is included in at least one embodiment of the present disclosure. Furthermore, the described features, advantages, and characteristics of the disclosure may be combined in any suitable manner in one or more embodiments. Those skilled in the relevant art will recognize that the disclosure may be practiced without one or more of the specific features or advantages of a particular embodiment. In other instances, additional features and advantages may be recognized in certain embodiments that may not be present in all embodiments of the disclosure.

Generally, all terms used herein are to be interpreted according to their ordinary meaning in the relevant technical field, unless a different meaning is clearly given and/or is implied from the context in which it is used. All references to a/an/the element, apparatus, component, means, step, etc. are to be interpreted openly as referring to at least one instance of the element, apparatus, component, means, step, etc., unless explicitly stated otherwise. Any feature of any of the embodiments disclosed herein may be applied to any other embodiment, wherever appropriate. Likewise, any advantage of any of the embodiments may apply to any other embodiments, and vice versa. Other objectives, features and advantages of the enclosed embodiments will be apparent from the following description.

FIG. 5 shows a part of the board 5 in the AIR product shown in FIG. 4. The board 5 is provided by a PCB vendor. As shown in FIG. 5, the board 5 is a multilayer PCB comprising a plurality of antenna layers 51 at the top and a plurality of radio layers 52 at the bottom. The board 5 is provided with a large amount of vias for electrical connection between different layers, such as a first via 53 for connecting two antenna layers 51, a second via 54 for connecting two radio layers 52, and a third via 55 for connecting one of the antenna layers 51 with one of the radio layers 52.

Both the first via 53 and the second via 54 may be a blind via, and the third via 55 may be a through via or a blind via. To form blind vias in the board 5, lots of extra process steps are needed, such as laminating an extra core by prepreg, drilling a hole, via plugging, and etching. Moreover, the antenna layers 51 and the radio layers 52 are made of different materials with different loss and electrical parameters. Thus, it is difficult to form the antenna layers 51 and the radio layers 52 in a single board, which puts forward higher requirements on the PCB vendor. Accordingly, the current one board solution is much more expensive than separately forming an antenna PCB and a radio PCB.

In addition, in the current one board solution, a multilayer PCB is used to support the antenna layers and the radio layers, which means the antenna layers and the radio layers have the same dimension. But in the actual design, the radio components supported by a given radio PCB may operate at different frequency bands, while the size and the spacing of the antenna elements, and thus the size of the antenna PCB, will vary as the operating frequency band changes. The current one board solution is not applicable to different radio and antenna use cases.

In view of the above, the present disclosure proposes a new AIR product, which can achieve a high integration level while reducing costs, and which is applicable to different radio and antenna use cases.

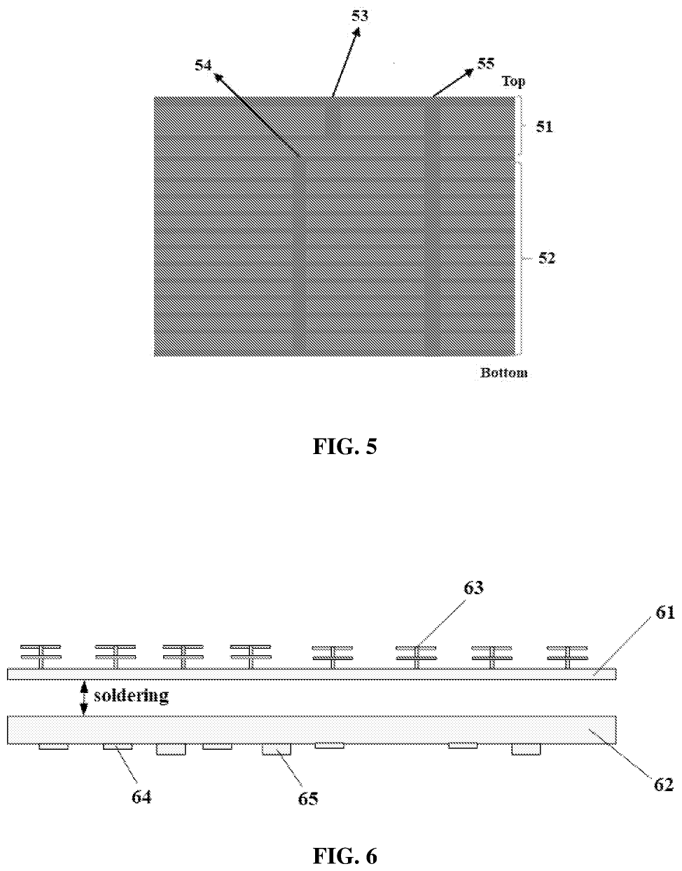

FIG. 6 shows a portion of an AIR product according to an embodiment of the present disclosure. The AIR product according to this embodiment includes an antenna module and a radio module. The antenna module includes an antenna board 61, and a plurality of antenna elements 63 soldered to the antenna board 61. The antenna module may further include a power divider, an impedance transformer, and a calibration network, which are not shown in FIG. 6 and which may also be soldered to the antenna board 61. The radio module includes a radio board 62, and a plurality of radio components soldered to the radio board 62. The radio components include a plurality of baseband components 64, which may be a field-programmable gate array (FPGA), a digital signal processor (DSP), a central processing unit (CPU), and a random-access memory (RAM). The radio components further include a plurality of surface mounted filters 65, which may be CWG filters or metal cavity filters such as sheet metal filters.

The antenna elements 63 are soldered to a first side (upper side in FIG. 6) of the antenna board 61. Although not shown, it will be appreciated by those skilled in the art that the power divider, the impedance transformer, and the calibration network may also be soldered to the first side of the antenna board 61. The baseband components 64 and the surface mounted filters 65 are soldered to a first side (lower side in FIG. 6) of the radio board 62. Although not shown, it will be appreciated by those skilled in the art that some radio components may be soldered to a second side (upper side in FIG. 6) of the radio board 62. A second side (lower side in FIG. 6) of the antenna board 61 is soldered to the second side of the radio board 62, as shown in FIG. 6.

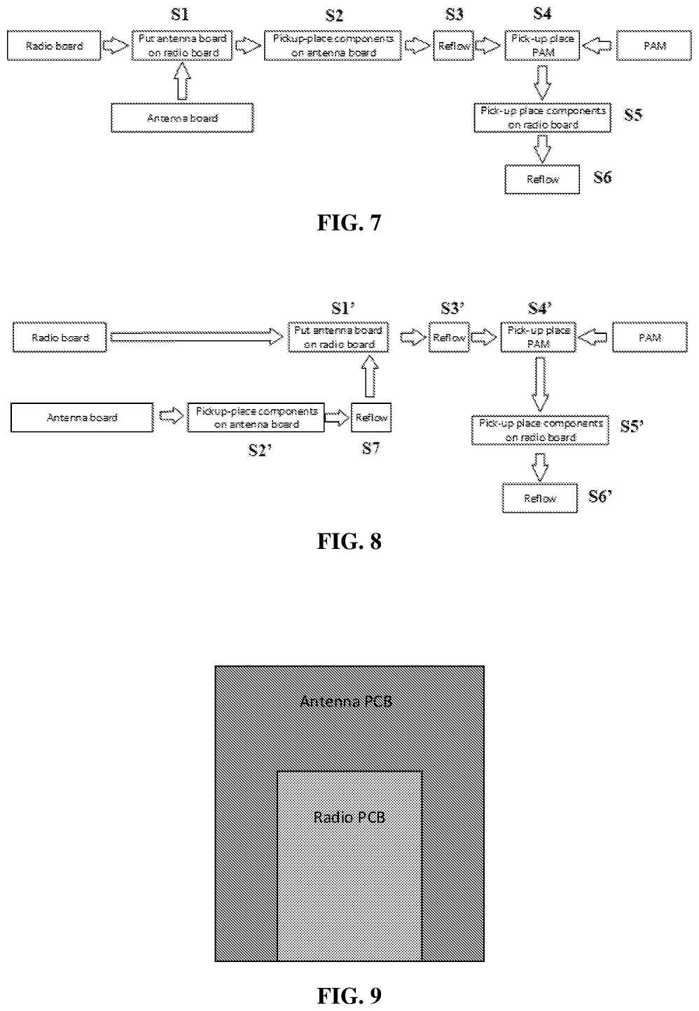

FIG. 7 illustrates a process for producing the AIR product shown in FIG. 6. Firstly, the antenna board 61 and the radio board 62 are manufactured by PCB vendors. As shown in FIG. 7, a Power Amplifier Module (PAM) is also provided, which includes a plurality of RF amplification elements integrated into a small PCB.

The antenna board 61, the radio board 62 and the PAM are fed to a Surface Mount Assembly (SMA) line. At step S1, the antenna board 61 and the radio board 62 are put together by a robotic arm, such that the second side of the antenna board 61 faces the second side of the radio board 62. At step S2, the antenna elements 63 are placed onto the first side of the antenna board 61 by the robotic arm. Then, at step S3, with the antenna board 61 and the radio board 62 being fixed in place by a fixture, the antenna elements 63 are soldered to the first side of the antenna board 61 in a relow oven, and at the same time, the second side of the antenna board 61 is soldered to the second side of the radio board 62.

At step S4, the PAM is placed onto the first side of the radio board 62 by the robotic arm. At step S5, the radio components including the baseband components 64 and the surface mounted filters 65 are placed onto the first side of the radio board 62 by the robotic arm. Then, at step S6, the PAM and the radio components are soldered to the first side of the radio board 62 in the relow oven.

FIG. 8 illustrates another process for producing the AIR product shown in FIG. 6. Similar steps are denoted by same reference signs with an apostrophe (′). This process differs from the above process shown in FIG. 7 only in that the antenna elements 63 are soldered to the antenna board 61 before the antenna board 61 and the radio board 62 are soldered together. In other words, the step S2′ is carried out before the step S1′, and a step S7 is interposed between the steps S2′ and S1′. At the step S7, the antenna elements 63 are soldered to the first side of the antenna board 61 in the relow oven. Accordingly, at the step S3′, only the soldering of the second side of the antenna board 61 to the second side of the radio board 62 is carried out.

It will be appreciated by those skilled in the art that the steps S4-S6, S4′-S6′ can also be carried out before the steps S1, S1′ and S3, S3′. There is no limitation on the sequence of the soldering steps. That is, the soldering of the antenna elements 63 to the antenna board 61, the soldering of the PAM or the radio components to the radio board 62, and the soldering of the antenna board 61 to the radio board 62 can be carried out at any order. They can also carried out simultaneously in the same reflow over. Also, the step S5, S5′ may be carried out before or simultaneously with the step S4, S4′.

Advantages of embodiments of the disclosure will be described below.

According to the above embodiments, the antenna board and the radio board are separately manufactured by PCB vendor(s) and then soldered together at the SMA line. Compared with supplying a hybrid PCB comprising antenna layers and radio layers, it is much easier for the PCB vendor(s) to manufacture an antenna PCB and a radio PCB, so the cost is greatly reduced.

Moreover, as the antenna board and the radio board are soldered together, a new one board solution similar to that shown in FIG. 4 is provided, which is flexibly applicable to different radio and antenna use cases.

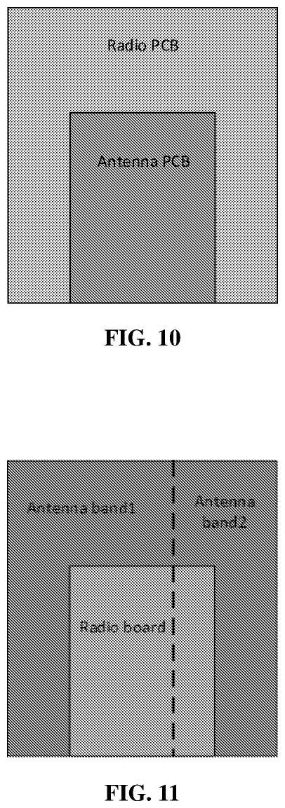

For example, a radio PCB may be manufactured to have substantially the same dimension as that of an antenna PCB for antenna array operating at 3.5G Hz. For antenna array operating at 2.6G Hz, another antenna PCB which is larger than the radio PCB is required (see FIG. 9). For antenna array operating at 4.9G Hz, a still another antenna PCB which is smaller than the radio PCB is required (see FIG. 10), and in this case some radio components can also be soldered to the side of the radio PCB on which the antenna PCB is soldered. The AIR product according to the above embodiments can be flexibly applied to these cases.

Further, the AIR product according to the above embodiments is very useful in multi-band design (see FIG. 11), in which the antenna PCB supporting multiple antenna arrays in different bands is much larger than the radio PCB supporting multiple bands.

In the above embodiments of the present disclosure, the antenna module comprises an antenna board 61, and the antenna elements 63, the power divider, the impedance transformer, and the calibration network are all soldered to the antenna board 61. However, the present disclosure is not limited to these embodiments. For example, in another embodiment of the present disclosure, the antenna module may not include an antenna board, and the antenna module comprising the antenna elements and the power divider, and optionally the impedance transformer and the calibration network, are directly soldered to the radio board. The term “directly soldered” herein does not exclude the presence of possible intermediate supporter; rather, it intends to mean that no antenna board is needed. Soldering the antenna module without an antenna board to the radio board can also achieve the advantages as mentioned hereinabove.

References in the present disclosure to “an embodiment”, “another embodiment” and so on, indicate that the embodiment described may include a particular feature, structure, or characteristic, but it is not necessary that every embodiment includes the particular feature, structure, or characteristic. Moreover, such phrases are not necessarily referring to the same embodiment. Further, when a particular feature, structure, or characteristic is described in connection with an embodiment, it is submitted that it is within the knowledge of one skilled in the art to implement such feature, structure, or characteristic in connection with other embodiments whether or not explicitly described.

It should be understood that, although the terms “first”, “second” and so on may be used herein to describe various elements, these elements should not be limited by these terms. These terms are only used to distinguish one element from another. For example, a first element could be termed a second element, and similarly, a second element could be termed a first element, without departing from the scope of the disclosure. As used herein, the term “and/or” includes any and all combinations of one or more of the associated listed terms.

The terminology used herein is for the purpose of describing particular embodiments only and is not intended to limit the present disclosure. As used herein, the singular forms “a”, “an” and “the” are intended to include the plural forms as well, unless the context clearly indicates otherwise. It will be further understood that the terms “comprises”, “comprising”, “has”, “having”, “includes” and/or “including”, when used herein, specify the presence of stated features, elements, and/or components, but do not preclude the presence or addition of one or more other features, elements, components and/or combinations thereof. The terms “connect”, “connects”, “connecting” and/or “connected” used herein cover the direct and/or indirect connection between two elements.

The present disclosure includes any novel feature or combination of features disclosed herein either explicitly or any generalization thereof. Various modifications and adaptations to the foregoing exemplary embodiments of this disclosure may become apparent to those skilled in the relevant arts in view of the foregoing description, when read in conjunction with the accompanying drawings. However, any and all modifications will still fall within the scope of the non-Limiting and exemplary embodiments of this disclosure.

1. An antenna-integrated radio product, comprising an antenna module and a radio module, the antenna module comprising a plurality of antenna elements and a power divider, the radio module comprising a radio board and a plurality of radio components, wherein the antenna module and the radio components are soldered to opposite sides of the radio board.

2. The antenna-integrated radio product according to claim 1, wherein the antenna module comprises an antenna board, the antenna elements and the power divider are soldered to a first side of the antenna board, and a second side of the antenna board is soldered to the radio board.

3. The antenna-integrated radio product according to claim 2, wherein the size of the antenna board is different from the size of the radio board.

4. The antenna-integrated radio product according to claim 2, wherein the antenna elements soldered to the antenna board are grouped in multiple bands.

5. The antenna-integrated radio product according to claim 2, wherein the antenna module further comprises an impedance transformer and a calibration network soldered to the first side of the antenna board.

6. The antenna-integrated radio product according to claim 1, wherein the antenna module is directly soldered to the radio board.

7. The antenna-integrated radio product according to claim 6, wherein the antenna module further comprises an impedance transformer and a calibration network.

8. The antenna-integrated radio product according to claim 1, wherein the radio components comprises a surface mounted filter and/or one or more baseband components selected from a group consisted of a field-programmable gate array (FPGA), a digital signal processor (DSP), a central processing unit (CPU), and a random-access memory (RAM).

9. The antenna-integrated radio product according to claim 1, wherein further radio components are provided on a side of the radio board to which the antenna module is soldered.

10. A method for producing an antenna-integrated radio product, the antenna-integrated radio product comprising an antenna module and a radio module, the antenna module comprising an antenna board and a plurality of antenna elements, the radio module comprising a radio board and a plurality of radio components, wherein the method comprises steps of:
a) soldering the antenna elements to a first side of the antenna board;
b) soldering the radio components to a first side of the radio board;
c) putting the antenna board together with the radio board, such that a second side of the antenna board that is opposite to the first side thereof faces a second side of the radio board that is opposite to the first side thereof; and
d) soldering the second side of the antenna board to the second side of the radio board.

11. The method according claim 10, wherein the step a) or the step b) is carried out simultaneously with, before or after the step d).

12. The method according to claim 10, wherein the steps a), b) and d) are carried out in the same reflow oven.

13. A method for producing an antenna-integrated radio product, the antenna-integrated radio product comprising an antenna module and a radio module, the antenna module comprising a plurality of antenna elements, a power divider, an impedance transformer, and a calibration network, the radio module comprising a radio board and a plurality of radio components, wherein the method comprises steps of:
a) soldering the radio components to a first side of the radio board;
b) putting the antenna elements, the power divider, the impedance transformer, and the calibration network on a second side of the radio board that is opposite to the first side thereof;
c) soldering the antenna elements and the power divider to the second side of the radio board; and
d) soldering the impedance transformer and the calibration network to the second side of the radio board.

14. The method according claim 13, wherein the step c) or the step d) is carried out simultaneously with, before or after the step a).

15. The method according to claim 13, wherein the steps a), c) and d) are carried out in the same reflow oven.
